(19) United States
(12) Patent Application Publication
(10) Pub. No.: US 2008/0264465 A1
(43) Pub. Date: Oct. 30, 2008

(54) Modular Sub-Assembly of Semiconductor Strips

(76) Inventors: Mark John Kerr, South Australia (AU); Pierre Jacques Verlinden, South Australia (AU)

Correspondence Address: WOOD, PHILLIPS, KATZ, CLARK & MORTIMER, 500 W. MADISON STREET, SUITE 3800, CHICAGO, IL, 60661, US

(21) Appl. No.: 11/883,083

(22) PCT Filed: Jan. 27, 2006
(86) PCT No.: PCT/AU2006/000100

§ 371 Date: Apr. 17, 2008

(30) Foreign Application Priority Data
Jan. 27, 2005 (AU) 2005900338

(51) Int. Cl. H01L 31/042

(52) U.S. Cl. 136/244; 257/E31.032

(57) ABSTRACT

A modular subassembly (100) of elongated semiconductor strips (110) and a method of making the same are disclosed. Supporting media (120) supports the elongated semiconductor strips (110). Elongated semiconductor strips (110) are disposed on and affixed to the supporting media (120). The supporting media (120) may be configured in a number of ways.

### FIELD OF THE INVENTION

The present invention relates generally to semiconductor processing, and in particular to assembling semiconductor devices.

### BACKGROUND

The photovoltaic solar cell industry is highly cost sensitive in terms of the efficiency of the power produced by a solar cell and the cost of producing the solar cell. As only a low percentage of the total thickness of a solar cell is used to generate power, minimising the thickness of the solar cell and yielding more solar cells from a piece of silicon are increasingly important.

International (PCT) Application No. PCT/AU2004/000594 filed on 7 May 2004 (WO 2004/100252 A1 published on 18 Nov. 2004) in the name of Origin Energy Solar Pty Ltd et al and entitled “Separating and Assembling Semiconductor Strips” discloses a method for separating elongated strips or sliver cells from a wafer of semiconductor material and assembling them to form “sliver” photovoltaic solar modules. The slivers are removed from the wafer using a vacuum source. Vacuum is applied to the face of an elongated semiconductor sliver forming the edge or being adjacent to the edge of the wafer. The wafer and the vacuum source are then displaced relative to each other to separate each sliver from the wafer. A separated sliver has a width substantially equal to the wafer thickness and a thickness dimension less than the width. The separated slivers are assembled into an array using a parallel, castellated timing belt assembly. Adhesive is applied in strips on a substrate to support the separated slivers and/or to provide optical coupling to the substrate, and then those slivers are transferred to the substrate. Visual defects may arise in the adhesive or epoxy due to air gaps. Such slivers minimize the thickness of the photovoltaic solar cell and yield more photovoltaic solar cells from the piece of silicon (e.g., the wafer).

Photovoltaic modules made with methods such as that described in International (PCT) Patent Publication No. WO 2004/100252 A1 typically use a monolithic process in which the sliver cells are assembled directly onto a substrate, which defines the size of the final module product. Such a monolithic process has a number of disadvantages, including:

a. Assembly equipment is expensive and has significant customisation (requiring equipment maintenance, upgrading, etc);

b. The equipment requires substantial manual intervention;

c. Module products from such processes and machines are limited in size due to the monolithic nature of the existing process;

d. Module products from the process carry weight and cost penalties due to a bi-glass construction;

e. Module products from the process carry a cost penalty due to modules being limited in size;

f. Module products from the process/equipment have constrained features; certain aspects of the module product such as number of cells per bank (equivalent to current/voltage trade off), cosmetic appearance, etc., cannot be easily varied;

g. The processes require too high a yield at the different steps to be successful at a manufacturing level due to the monolithic nature of the existing process; and

h. The processes are susceptible to tolerance stack-up due to the monolithic nature of the existing process.

A need exists for a modular subassembly of semiconductor strips and modular panels that provide flexibility, especially in handling, assembly of photovoltaic modules, and testing. More particularly, a need exists to develop a photovoltaic module process for sliver cells alleviating or overcoming such limitations.

### SUMMARY

In accordance with an aspect of the invention, a modular subassembly of elongated semiconductor strips is provided. The subassembly comprises supporting media to support elongated semiconductor strips, and a plurality of elongated semiconductor strips disposed on and affixed to the supporting media.

The elongated semiconductor strips may be disposed on the supporting media in a parallel configuration.

The elongated semiconductor strips may be formed from a wafer of semiconductor material.

Equipment including one or more of robotics handling equipment, a lay-up machine, a tabbing machine, and a stringer are used to handle the subassembly.

The supporting media may be transparent or at least translucent, or may be opaque.

The supporting media may be fiberglass, metal, ceramics, insulators, or plastics. The plastics may include polyvinyl fluoride (PVF), polyester, fluoropolymer film (ETFE), or polyimide.

The supporting media may be able to withstand processing temperatures in the range selected from the group consisting of about 100° C. and about 250° C., about 100° C. to about 170° C., about 200° C. to about 250° C., and about 100° C. to about 200° C.

The supporting media may comprise insulative material and conductive metal portions formed with the insulative material, or conductive material and insulative portions formed with the conductive material.

The supporting media may be configured as tracks, ribbons, full sheets, processed full sheets, film, rectangles, a ladder configuration, a sheet with perforations or punch holes, and angled bars.

The supporting media may comprise at least one of ribbons and tracks, and further comprises additional structural support for bracing.

The elongated semiconductor strips may be photovoltaic cells. The subassembly may be a photovoltaic device.

The sub-assembly may be flexible, conformable, or rigid.

In accordance with another aspect of the invention, a tabbed subassembly is provided, comprising a subassembly in accordance with the preceding aspects, and a plurality of tabs coupled to the subassembly for connecting the subassembly with another tabbed subassembly.

In accordance with yet another aspect of the invention, a panel is provided, comprising at least two tabbed subassemblies in accordance with the above aspect, and at least one interconnecting mechanism coupling at least one tab of a tabbed subassembly with at least one tab of another tabbed subassembly. The tabbed subassemblies may be interconnected in series or in parallel dependent upon the current or voltage to be produced.

### BRIEF DESCRIPTION OF THE DRAWINGS

Embodiments of the invention are described, by way of example only, with reference to the accompanying drawings, in which:

FIG. 1 is a top plan view of a modular subassembly of semiconductor strips in accordance with an embodiment of the invention;

FIG. 2 is a top plan view of the modular subassembly of FIG. 1 with conductive material deposited between the semiconductor strips;

FIG. 3 is a top plan view of the modular subassembly of FIG. 2 with the slivers and interconnections soldered together;

FIG. 4 is a top plan view of a panel including the modular subassembly of FIG. 3 on a flexible backsheet;

FIG. 5 is a cross-sectional side view of the fully assembled panel of FIG. 4;

FIG. 6 is a top plan view of two displaced tabbed subassemblies that have conductive tabs at opposite ends for coupling the subassemblies together;

FIG. 7 is a top plan view of the two tabbed subassemblies of FIG. 6 connected together;

FIG. 8 is a top plan view of the two connected tabbed subassemblies of FIG. 7 with solder affixing the conductive tabs together;

FIG. 9 is a top plan view of a modular subassembly of semiconductor strips with reinforcement in accordance with another embodiment of the invention;

FIG. 10 is a top plan view of a modular subassembly of semiconductor strips;

FIG. 11 is a top plan image of a 75 watt panel comprising a number of sub-assemblies;

FIG. 12 is a top plan image of an example of a sub-assembly comprising 20 banks, each of 35 cells per bank, giving 700 sliver cells in total;

FIG. 13 is a top plan image of an example of a sub-assembly comprising 10 banks, each of 70 cells per bank, giving 700 sliver cells in total;

FIG. 14 is a top plan image of an example of an experimental sub-assembly made on track type substrate;

FIG. 15 is a top plan image providing a close up of an experimental sub-assembly made on track type substrate showing cream coloured track type substrate; and

FIG. 16 is a top plan image of a 150 watt panel comprising a number of sub-assemblies

### DETAILED DESCRIPTION

A modular subassembly of elongated semiconductor strips and a method of providing the same are described hereinafter. In the following description, numerous specific details, including semiconductor materials, adhesives, conductive materials, semiconductor strip or sliver dimensions, supporting media, and the like are set forth. However, from this disclosure, it will be apparent to those skilled in the art that modifications and/or substitutions may be made without departing from the scope and spirit of the invention. In other circumstances, specific details may be omitted so as not to obscure the invention.

The embodiments of the invention provide a modular sub-assembly of elongated semiconductor strips or slivers, which are preferably photovoltaic solar cells. The slivers may be of the type disclosed in the above-noted International (PCT) Application No. PCT/AU2004/000594, which is incorporated herein by reference. Each subassembly may comprise any number of slivers dependent upon the voltage to be produced (e.g., 6, 35, 70, 300 or 1000 slivers). Alternatively, the subassembly may be “endless” (e.g., rolls of slivers). In the following description, the subassemblies are described as comprising 35 or 70 slivers, by way of example, but other numbers of slivers may be practiced without departing from the scope and spirit of the invention, dependent upon any of a number of circumstances including the desired output voltage to be produced by the subassembly. For example, a subassembly of 35 slivers connected in series may produce a voltage (e.g., 0 V to 25 V) suitable to charge a 12 V battery.

The embodiments of the invention provide an intermediate product, termed a sub-assembly. A sub-assembly has the property that while the sub-assembly of sliver cells is relatively small, it can be used to make final module products of arbitrary size (scalability in the final module product built from sub-assemblies). The sub-assemblies allow big modules to be built from small sub-assemblies, which means that the starting machines only need to be able to operate over small sub-assemblies rather than over big modules. The sub-assembly invention enables creation of an intermediate product, which is relatively small, but can be used to make final module products of arbitrary size (the scalability in the final product).

A sub-assembly may comprise a single bank of slivers in parallel, or multiple banks of slivers in parallel, all connected by a single tab. Images are provided in the Figures depicting sub-assemblies with multiple banks.

### I. Modular Subassembly of Slivers

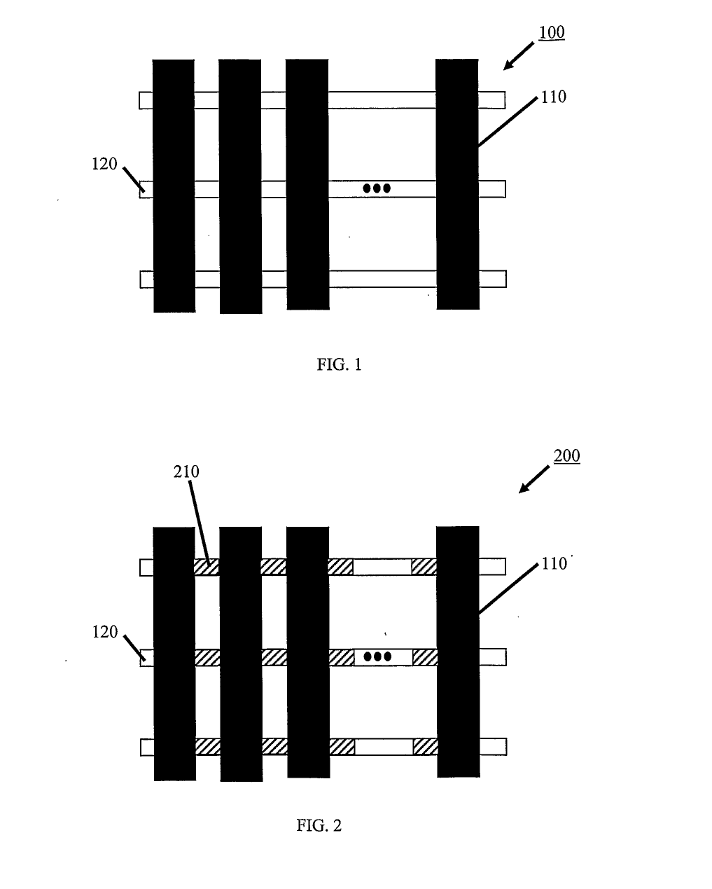

FIG. 1 provides an overview of a sliver subassembly 100 comprising a number of elongated semiconductor strips 110 (i.e., slivers) disposed in a parallel configuration on supporting media 120. For ease of illustration, FIG. 1 only depicts four slivers 110. The wafer from which the slivers 110 of semiconductor material are formed may be single crystal silicon or multi-crystalline (or poly-crystalline) silicon, for example. However, other semiconductor materials may be practiced without departing from the scope and spirit of the invention. For purposes of illustration only, a specific configuration of slivers is given as an example. The slivers may each be about 40 mm to about 200 mm in length, about 0.3 mm to about 2.0 mm in width, and about 10 μm to about 300 μm in thickness. The foregoing ranges are provided to illustrate broadly the relative sizes of slivers (or elongated semiconductor strips). The slivers are quite thin.

In FIG. 1, the supporting media 120 are arranged in parallel and are oriented lengthwise in a manner that is orthogonal to the lengths of the slivers 110. In this example, each supporting medium 120 is formed as a ribbon or a track, but as described hereinafter other configurations may be practiced including films. A track may be considered to be a more rigid structure than a ribbon, which may be flexible. While specific configurations, materials, and properties for the supporting media are set forth to illustrate various implementations, it will be apparent to those skilled in the art that numerous variations are possible. For example, the supporting media 120 may be configured in rectangles, a ladder configuration, a sheet with perforations or punch holes, and angled bars (akin to the ladder configuration).

While three supporting media 120 are depicted in FIG. 1, it will be appreciated by those skilled in the art that other numbers of supporting media may be practiced. For example, two supporting media 120 instead of three supporting media may be sufficient to support the slivers 110, or even a single supporting media of sufficient width may be able to support the slivers 110.

The subassemblies 100 may be self-supporting, but this is not essential. Instead, the subassemblies 100 may be flexible as long as they have sufficient strength to remain together. That is, the supporting media 120 may be flexible, provided the media 120 can maintain the relative positions of the slivers. Such a subassembly 100 can easily be used with automation equipment (e.g., robotic handlers, pick and place robots etc). In other example embodiments, the sub-assembly may be conformable, or rigid.

The dimensions of the supporting media are a function of sliver width and length, as well as the pitch between adjacent slivers in a subassembly. The supporting media 120 may be transparent or at least translucent, but this is not necessarily the case dependent upon the application. Opaque materials may be used.

The supporting media 120 may made from any of a number of materials, including:
fiberglass (e.g. formed as a ribbon);
metal (e.g., copper, silver, alloys);
ceramics (e.g., silica carbide or alumina);
transparent polyvinyl fluoride (PVF) such as TEDLAR® manufactured by DuPont, or the like (formed as a ribbon, film, or sheet);
clear polyester (e.g. formed as a film);
transparent fluoropolymer film (ETFE) such as TEFZEL® manufactured by DuPont or AFLEX (e.g. formed as a ribbon or sheet);
other plastics;
a polyimide film such as KAPTON® manufactured by DuPont (e.g., formed as a ribbon or film). KAPTON® can withstand temperatures up to 400° C.;
silicones or other laminating media, such as Ethylene Vinyl Acetate (EVA) or Poly Vinyl Butyl (PVB); and rubbers.

Besides the above enumerated materials for the supporting media 120, numerous other materials may be practiced. Other materials that can be used include, for example, those that can sustain processing temperatures of: about 100° C. to about 170° C. for a laminating process; about 200° C. to about 250° C. for soldering; or about 100° C. to about 200° C. for curing. The supporting media need not be able to withstand these processing temperatures, since various room temperature materials and methods can be used for laminating, curing, etc. (for example, use room temperature curing silicones, resins, or potants for lamination). Furthermore, for supporting media that is processed at higher temperatures, the only requirement may be that the supporting media does not prevent, or significantly detract from, the functioning of the sub-assembly after the processing steps. For example, the supporting media is not required to support the sub-assembly after lamination (the laminate supplies the support), only not prevent the sub-assembly from functioning. In particular, the supporting media may “dissolve” during lamination or even be the lamination media.

In the embodiment shown in FIG. 1, the supporting media 120 are formed as tracks. However, the supporting media 120 may be ribbons of insulative material. Conductive metal portions may be formed with the ribbon to interconnect the slivers affixed to the ribbon. That is, a ribbon of insulative material with metal conductive portions may be practiced. Alternatively, a ribbon of conductive material with insulative portions may be practiced.

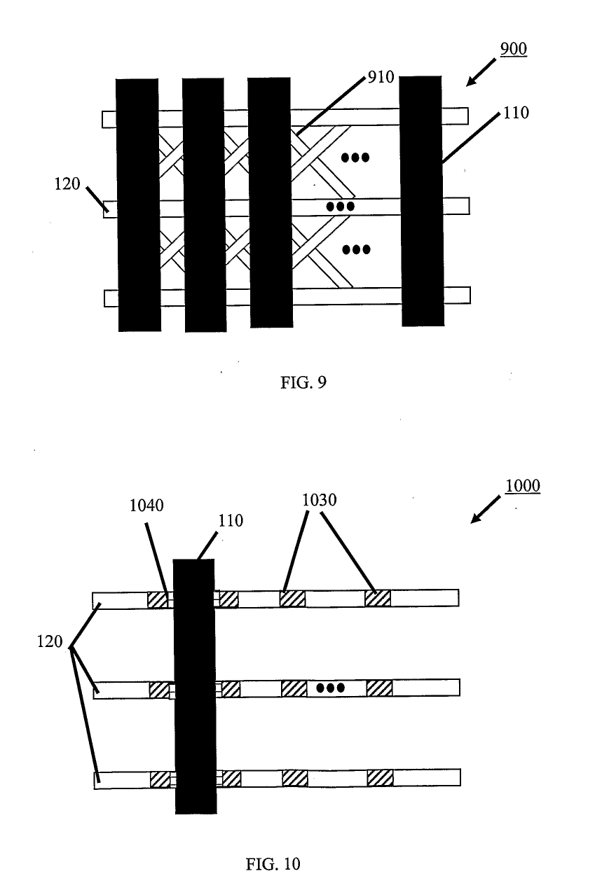

FIG. 9 is an overview of a sliver subassembly 900 comprising a number of slivers 110 in accordance with another embodiment of the invention, which is similarly configured to that of FIG. 1 except for additional structural support 910 for the supporting media 120. For ease of illustration, only four slivers 110 are depicted in FIG. 9. The supporting media 120 are oriented lengthwise in a manner that is orthogonal to the lengths of the slivers 110. In addition to the tracks of supporting media 120, cross-bars or bracing 910 of supporting media are provided to further strengthen the supporting media supporting the slivers 110. Thus, the supporting media has a lattice-like structure. Such cross-bars can be formed by processing full sheets to have perforations or apertures. For example, such cross-bar supporting media 910 resist torsion that might be applied along the longitudinal axes of the tracks 120. Other configurations of additional supporting media may be practiced without departing from the scope and spirit of the invention. The additional supporting media 910 may be transparent or translucent and may be made of the same material as the other supporting media 110. Alternatively, the additional supporting media 910 may be opaque.

FIG. 10 is a top plan view of a modular subassembly 1000 of semiconductor strips. For ease of illustration, only a single sliver 110 is shown. Conductive portions 1030 are formed on the supporting media 120 for interconnecting slivers 110. As shown in FIG. 10, the conductive portions 1030 are disposed in regular intervals along the tracks 120. The three tracks of supporting media 120 may be preconfigured or pre-printed with the conductive portions 1030, any adjacent pair of which can connect with a sliver 110 when disposed on the tracks 120. Other methods of providing conductive interconnections 1030 may be practiced without departing from the scope and spirit of the invention. For example, the tracks 120 may be made from polymide, polyvinyl fluoride, or fiberglass. The conductive portions 1030 may comprise:
conductive metal such as copper (Cu), silver (Ag), copper and tin (Cu+Sn), gold (Au),
conductive polymers,
conductive plastics,
conductive inks;
conductive oxides;
conductive epoxies, or
solder.
   Other conductive materials may be practiced for the conductive portions 1030 without departing from the scope and spirit of the invention.

In FIG. 10, the sliver 110 may be affixed to the tracks 120 using an epoxy, a curable resin, or other adhesive technology. Alternatively, the sliver 110 may be affixed to the tracks 120 without adhesive or the like but by virtue of adhesion resulting from the conductive interconnection portions 1030. For example, the conductive portions 1030 may be pre-printed and the slivers are pressed into the space between the interconnecting conductive portions 1030, which firmly hold the sliver in place. Still further, solder may be applied to the sliver cells and the conductive portions 1030 to affix the slivers to the tracks 120. While not shown in the drawings, the tracks may preconfigured with holes, indentations, texturing or the like, so that the adhesive material better adheres the sliver 110 to the tracks. Holes are preferably practiced as the holes allow vacuum to be applied through the holes to hold slivers in place, for example while the adhesive cures. Solder 1040 is then applied to connect the conductive portions 1030 with the slivers 110. In this manner, the slivers 110 are connected sequentially.

The sub-assemblies above are described in a basic format. There are additional processes or materials or steps that could be applied, which do not detract from the spirit of the invention. One such process might be conformal coating to the sub-assembly to provide protection to the subassembly; another is lamination that may be applied to the modular subassemblies to encapsulate the subassemblies.

### II. Tabbed Subassemblies

FIG. 6 illustrates a pair 600 of tabbed sliver subassemblies 100 in accordance with a further embodiment of the invention. Each subassembly 100 has a large number of slivers configured on tracks in the manner shown in FIG. 1. At the opposite terminal ends (lengthwise) of the subassemblies 100 are conductive tabs 610 for interconnecting subassemblies 100. The conductive tabs 610 may comprise strips of conductive metal such as copper (Cu), silver (Ag), copper and tin (Cu+Sn), gold (Au), or the like. Such tabs are well known to those skilled in the art. The tabs can be electrically connected to the sliver cells using the same method and materials that are used for connecting a sliver cell to another sliver cell (e.g., the tabs are another element in the parallel array). Other techniques, such as wire bonding, may be used. Similarly, the tabs may also be held by the supporting media, or may not.

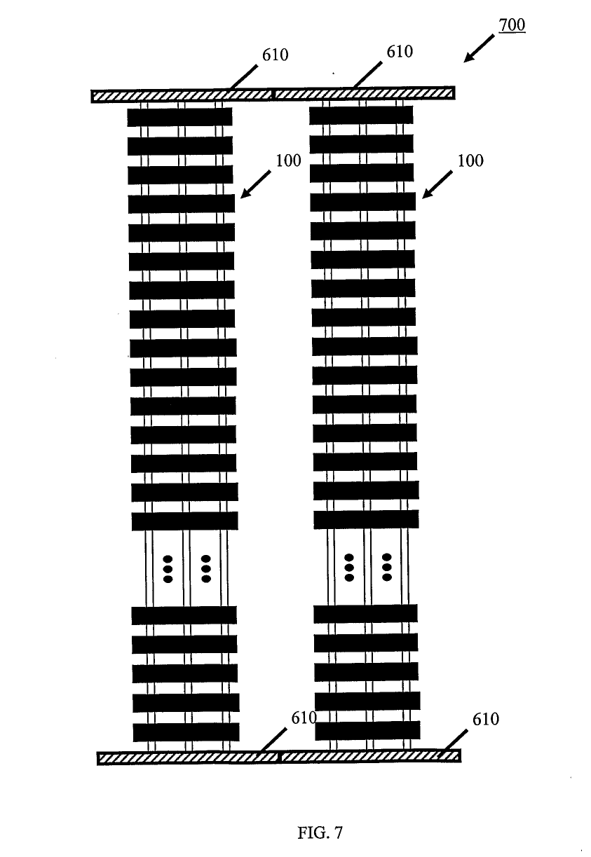

As shown in FIG. 7, the conductive tabs 610 of adjacent subassemblies 100 may be positioned adjacent to each other or brought into direct contact. The geometry of the tabs 610 may be symmetrically or asymmetrically configured. While connected in parallel in FIG. 7, the tabbed subassemblies may be connected in series by selectively connecting certain adjacent tabs and not interconnecting other adjacent tabs.

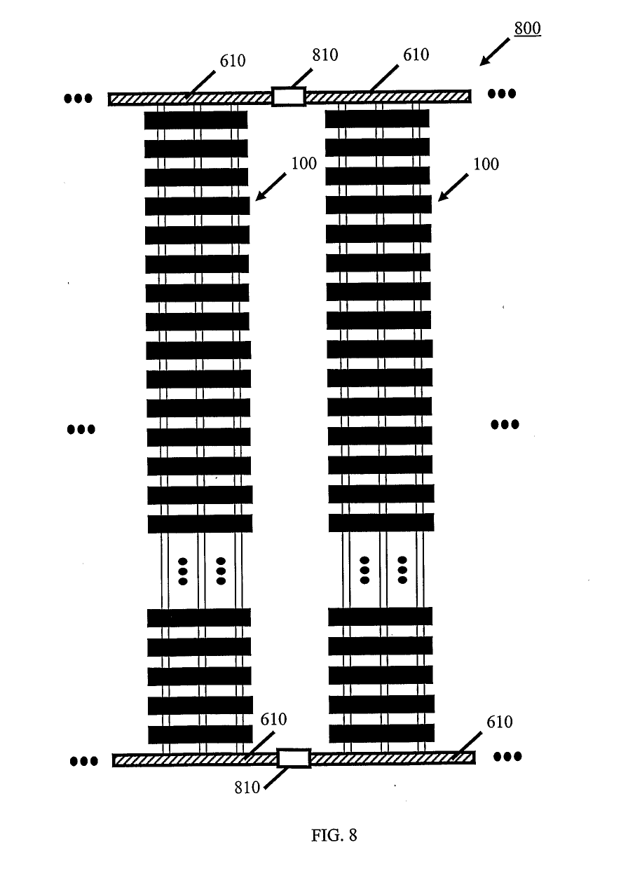

FIG. 8 shows solder 810 applied in one or more positions to the adjacent or contacting conductive tabs 610. While solder 810 is depicted in FIG. 8, it will be readily apparent to those skilled in the art that other interconnection mechanisms to couple tabs together may be practiced such as wire bonding or electrically conductive polymers or adhesives, for example, without departing from the scope and spirit of the invention. While FIG. 8 shows both upper and lower tabs 610 soldered together to provide a parallel connection of tabbed subassemblies, only one of the upper and lower pairs of tabs 610 need be soldered together to provide a series connection. By changing the configuration, voltage or current produced by the subassemblies can be varied. Also, the orientation of one subassembly relative to another may be varied to vary current or voltage.

Embodiments of the invention can produce high voltage, low current outputs with very small surface area, in contrast to existing technologies. Also, such modular subassemblies can be readily assembled into modules or panels of slivers using conventional machines, such as lay-up machines, stringers and tabbing machines, well known to those skilled in the art. The subassemblies may be provided without substrates (e.g. a glass substrate), which are generally heavy and bulky. This allows the subassemblies to be used in flexible modules and has benefits in terms of transportation and shipping. The subassemblies can be used in transparent, semitransparent or opaque (coloured) modules.

### III. Solar Cell Panels Using Modular Subassembly

The building of tabbed subassemblies allows the subassemblies to be used as a direct replacement for conventional solar cells. Stringing and lay-up machines may be used to interconnect the tabs of one subassembly to the tabs of a next subassembly (either in parallel or series; in a straight line or bent around corners etc) and create strings of subassemblies.

FIG. 2 illustrates the configuration 200 of a modular subassembly 100 of FIG. 1. While only a single subassembly 100 is depicted in FIG. 2, a string of subassemblies 100 may be formed and “tabbed” together. The slivers 110 are affixed to the three tracks 120. In this example, the tracks 120 are provided with conductive portions 210. The conductive portions 210 may for example be printed conductive epoxy containing silver. Other techniques and materials may be used to provide the conductive portions 210 between the slivers 110. Still further, the tracks 120 may be pre-printed with conductive portions or be pre-formed with the same in the manner shown in FIG. 10, instead of having the conductive portion 210 applied after the slivers 110 are affixed to the tracks 120.

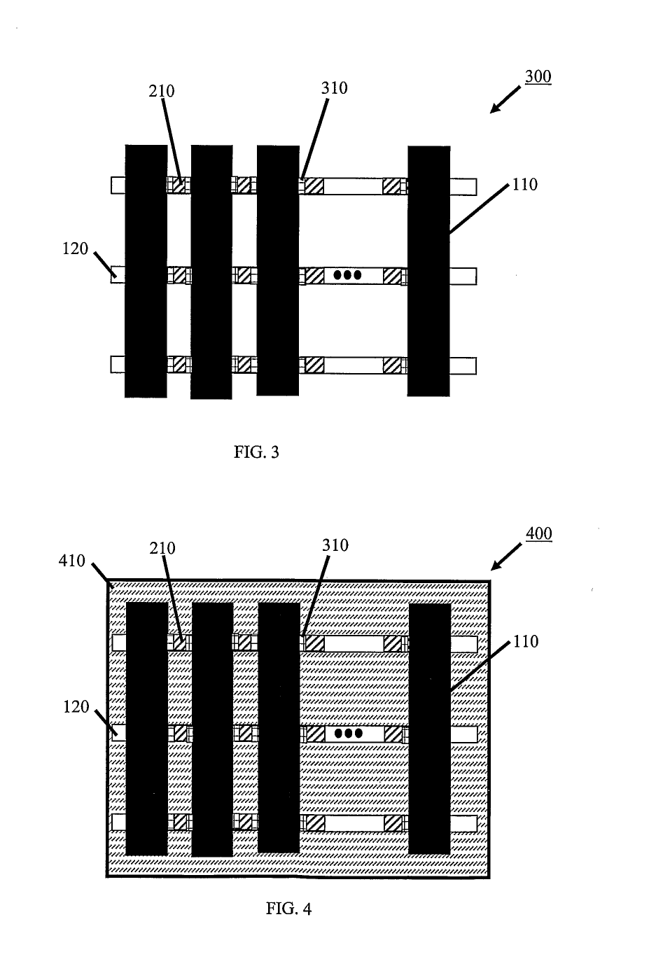

FIG. 3 illustrates the resulting configuration 300 of connecting the slivers 110 to the conductive portions 210 on the supporting media 120 using solder 310. This configuration 300 of the modular subassembly may be the final product, which can then be used to build solar cell panels and the like.

FIG. 4 illustrates the resulting configuration 400 of the modular subassembly 300 of FIG. 3 affixed to a backsheet 410 (such as plastic film of Tedlar-polyester (TP), Tedlar-Polyester-Tedlar (TPT), Tedlar-Aluminium-Tedlar (TAT), and the like). This may be done for example using a variety of adhesives or bonding media such as optical adhesives, silicones, resins or laminating films such as EVA, PVB etc.

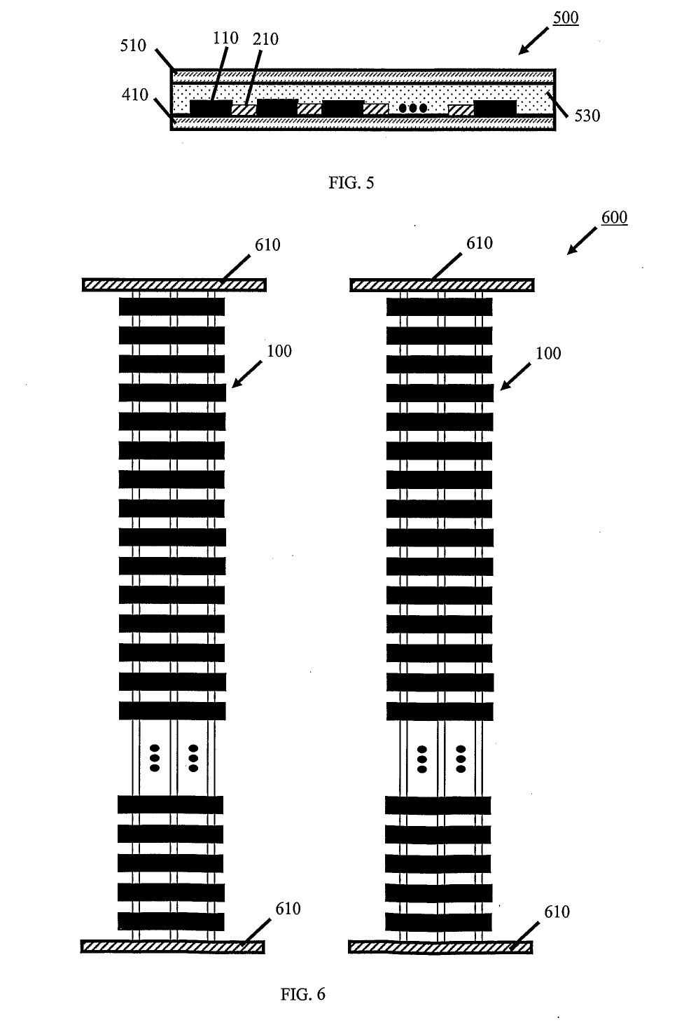

FIG. 5 is a lateral cross-sectional view of a fully assembled solar cell panel 500. The solar cell panel or module 500 may be made using a glass front 510, a layer or layers of EVA 530, a subassembly or a string of sub-assemblies (the strips 110 and conductive interconnection portions 210 are only shown in FIG. 5), another possible layer of EVA (not shown), and a layer of backsheet 410. To simplify the drawing, the supporting media and the solder are not shown. The modular subassemblies 300 are encapsulated with the EVA adhesive or other suitable optical adhesive. However, there are many alternatives to the above panel or module structure, including use a glass front and rear, a glass rear and plastic film front, a film on the front and rear to make a flexible module, a rigid or semi-rigid plastic sheet instead of glass, and a metal or fibre-glass layer on one side, for example.

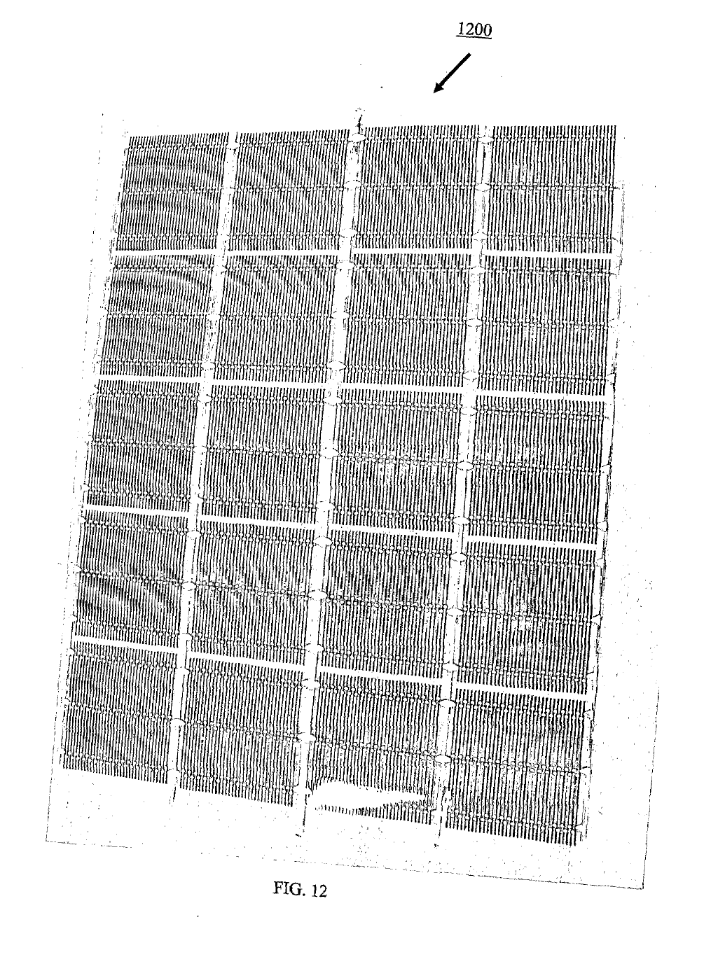

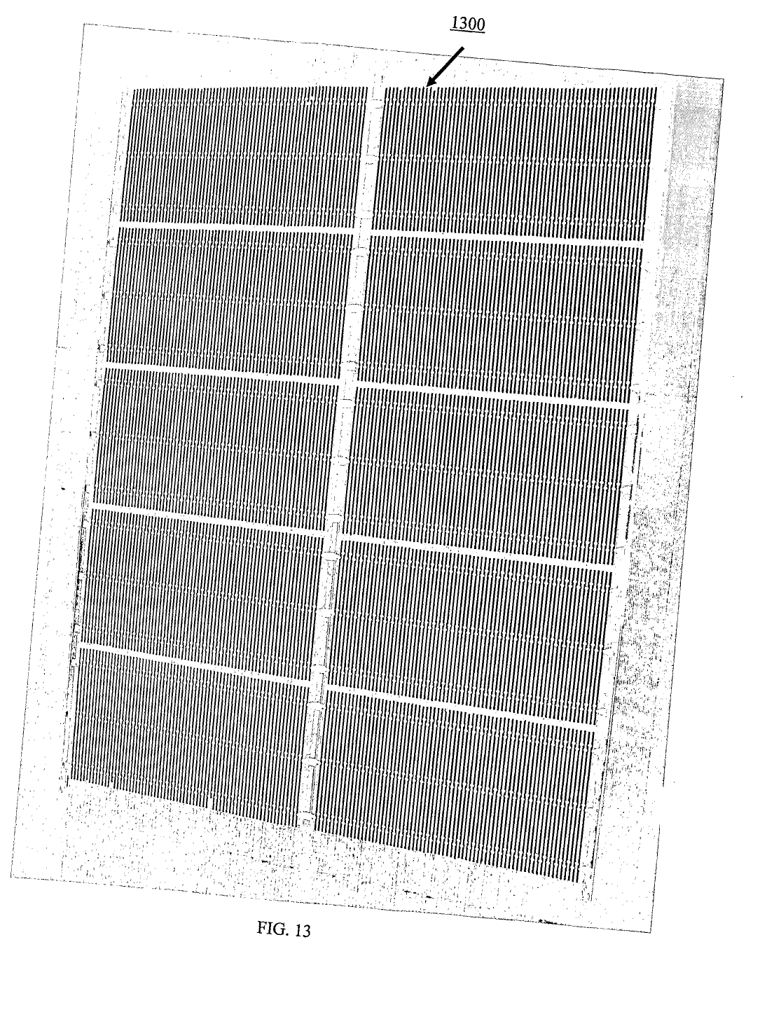

FIG. 12 is a top plan image of an example of a sub-assembly 1200 comprising 20 banks, each of 35 cells per bank, giving 700 sliver cells in total. The sub-assembly 1200 of FIG. 12 is built using Polyethylene Terephthalate (PET) in the specific embodiment shown, but other materials may be practiced.

FIG. 13 is a top plan image of an example of a sub-assembly 1300 comprising 10 banks, each of 70 cells per bank, giving 700 sliver cells in total. The sub-assembly 1300 of FIG. 13 is built using fibreglass tissue in the specific embodiment shown, but other materials may be practiced. FIGS. 12 and 13 illustrate two different implementations in accordance with embodiments of the invention.

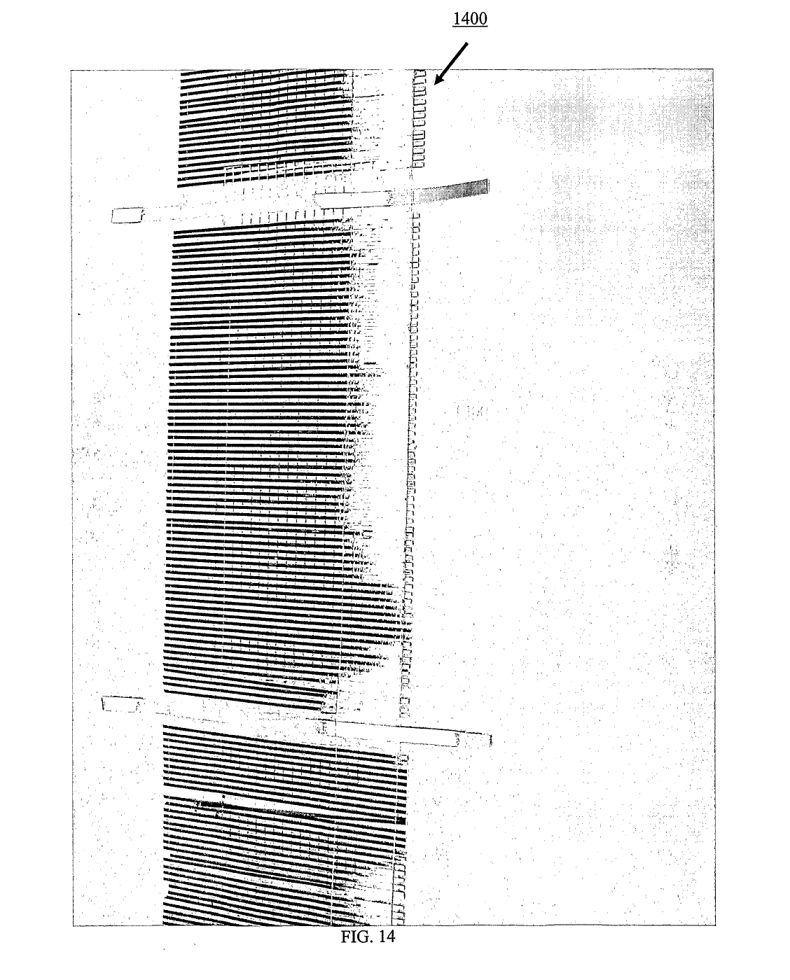

FIG. 14 is a top plan image of an example of an sub-assembly 1400 made on track type substrate.

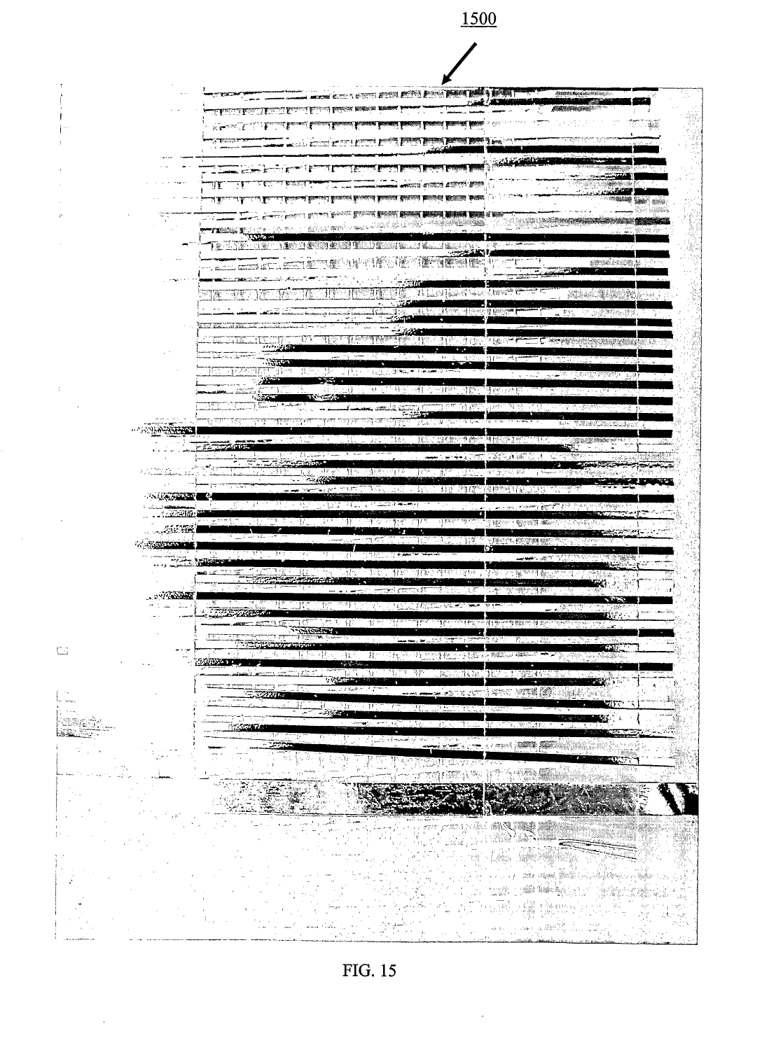

FIG. 15 is a top plan image providing a close up of a sub-assembly 1500 made on track type substrate showing cream coloured track type substrate.

### IV. Assembling Modular Subassembly

Numerous methods exist for assembling modular sub-assemblies and the potential materials such as the conductive interconnect, etc. Only a few are described here but many of the methods are conventional processes and equipment used in the semiconductor or other industries, such as:
Chip shooters
Pick and place equipment
Die attach equipment.
Wire bonders
Screen printing
Stencil printing
Dispensing
Pin transfer
Pad Printing
Stamping
Reflow
Wave soldering.

A first example of how to assemble modular sub-assemblies involves extension of International (PCT) Application No. PCT/AU2004/000594, which describes assembling banks of slivers onto the supporting media (including ribbons, tracks, films etc). The supporting media may be supplied in single pieces, held (e.g., by vacuum) or temporarily bonded to a more rigid support for the placement action. Alternatively, a roll of material may be used for the supporting media and sub-assemblies may be formed roll-to-roll. Adhesives may be used to bond the slivers to the supporting media and the adhesive may be applied beforehand by any of a number of known techniques including printing, stamping, or dispensing. Electrical interconnects may be applied before placement of the sliver cells or after placement using the same techniques, including printing, stamping or dispensing. Other methods such as wire bonding may also be used.

A second example of how to assemble modular sub-assemblies is by analogy with the assembly of printed circuit boards (PCB) as done in the Surface Mount Technology (SMT) industries where the PCB is a flexible PCB (typically polyimide). In this method, the flexible PCB is replaced with the supporting media and sliver cells are used to replace conventional electronic components. Again, standard techniques of dispensing and screen or stencil printing can be used to apply adhesives or material for electrical interconnection.

### V. Further Embodiments Employing Foils or Full Sheets

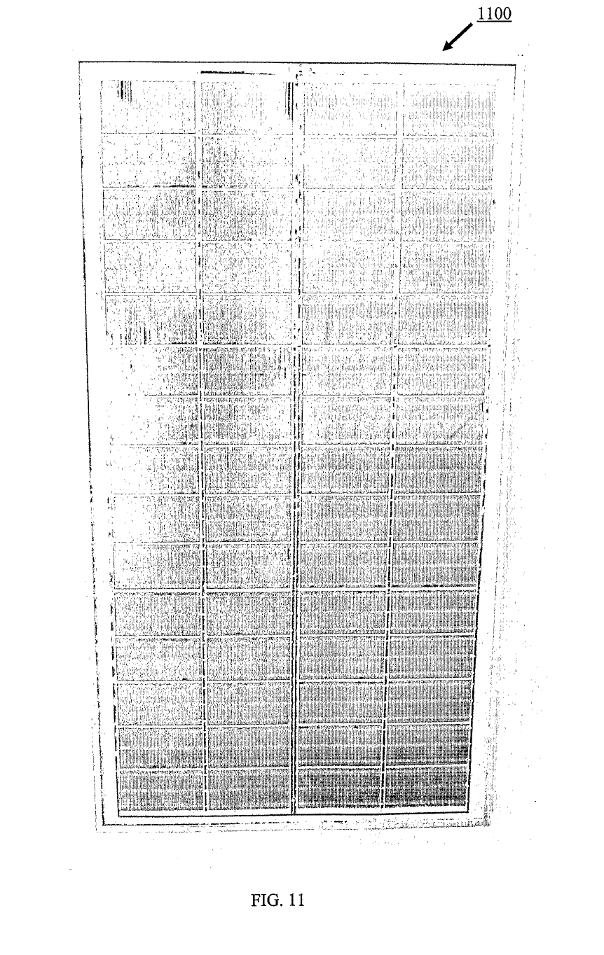

The embodiments of the invention may be practiced using foils or full sheets as the supporting media. Images of actual sub-assemblies based on full sheets and tracks are contained in FIGS. 11 to 16. The substrate may comprise materials such as fiberglass tissue, poly-carbonate and Polyethylene Terephthalate (PET). An additional material that may be practiced is carbon fibres.

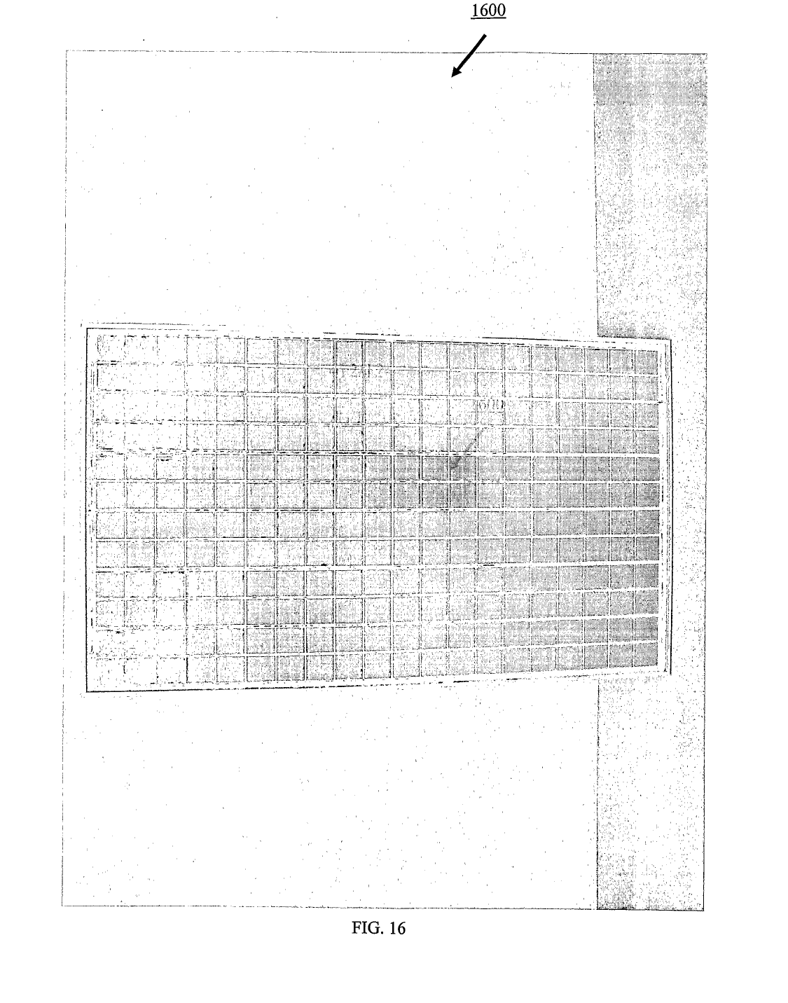

FIGS. 11 and 16 show 75 and 150 watt panels 1100, 1600 comprising six (6) sub-assemblies and twelve (12) sub-assemblies, respectively. The noted figures illustrate examples of photovoltaic modules fabricated using the sub-assemblies. FIG. 11 shows a module 1100 that contains six (6) sub-assemblies with each sub-assembly containing 10 banks of slivers cells and each bank has 70 sliver cells. Each sub-assembly measures approximately 400 mm by 300 mm. The module of FIG. 11 produces approximately 75 W of power. FIG. 16 shows a module 1600 that contains twelve sub-assemblies (same sub-assembly properties as those used in FIG. 11) and produces approximately 150 W of power. Modules with a smaller or larger number of sub-assemblies may be made and the sub-assemblies may be easily modified to contain a different number of sliver cells or banks of sliver cells.

In the foregoing manner, modular subassemblies of semiconductor strips and methods of providing the same have been described. While only a small number of embodiments have been disclosed, it will be apparent to those skilled in the art in the light of this disclosure that numerous changes and substitutions may be made without departing from the scope and spirit of the invention.

1. A modular subassembly of elongated semiconductor strips, comprising: supporting media to support elongated semiconductor strips; and a plurality of elongated semiconductor strips disposed on and affixed to said supporting media.

2. The subassembly according to claim 1, wherein said elongated semiconductor strips are disposed on said supporting media in a parallel configuration.

3. The subassembly according to claim 1, wherein said elongated semiconductor strips are formed from a wafer of semiconductor material.

4. The subassembly according to claim 1, wherein equipment including one or more of robotics handling equipment, a lay-up machine, a tabbing machine, and a stringer are used to handle said subassembly.

5. The subassembly according to claim 1, wherein said supporting media is transparent or at least translucent.

6. The subassembly according to claim 1, wherein said supporting media is opaque.

7. The subassembly according to claim 1, wherein said supporting media is selected from the group of materials consisting of fiberglass, metal, ceramics, insulators, and plastics.

8. The subassembly according to claim 7, wherein said plastics include polyvinyl fluoride (PVF), polyester, fluoropolymer film (ETFE), or polyimide.

9. The subassembly according to claim 1, wherein said supporting media is able to withstand processing temperatures in the range selected from the group consisting of about 1 OOOC and about 250° C., about 100° C. to about 170° C., about 200° C. to about 250° C., and about 100° C. to about 200° C.

10. The subassembly according to claim 1, wherein said supporting media comprises insulative material and conductive metal portions formed with said insulative material.

11. The subassembly according to claim 1, wherein said supporting media comprises conductive material and insulative portions formed with said conductive material.

12. The subassembly according to claim 1, wherein said supporting media is configured as tracks, ribbons, full sheets, processed full sheets, film, rectangles, a ladder configuration, a sheet with perforations or punch holes, and angled bars.

13. The subassembly according to claim 1, wherein said supporting media comprises at least one of ribbons and tracks, and further comprises additional structural support for bracing.

14. The subassembly according to claim 1, wherein said elongated semiconductor strips are photovoltaic cells.

15. The subassembly according to claim 14, wherein said subassembly is a photovoltaic device.

16. The subassembly according to claim 1, wherein said sub-assembly is flexible.

17. The subassembly according to claim 1, wherein said sub-assembly is conformable.

18. The subassembly according to claim 1, wherein said sub-assembly is rigid.

19. A tabbed subassembly, comprising: a subassembly in accordance with claim 1; and a plurality of tabs coupled to said subassembly for connecting said subassembly with another tabbed subassembly.

20. A panel, comprising: at least two tabbed subassemblies in accordance with claim 19 and at least one interconnecting mechanism coupling at least one tab of a tabbed subassembly with at least one tab of another tabbed subassembly.

21. The panel according to claim 20, wherein said at least two tabbed subassemblies are interconnected in series or in parallel dependent upon the current or voltage to be produced.
